(19) United States
(12) Patent Application Publication
(10) Pub. No.: US 2008/0194853 A1
(43) Pub. Date: Aug. 14, 2008

(54) Novel Iridium Complex and Organic Electroluminescence Device Using the Same

(75) Inventors: Tae-hyung Kim, Gyeonggi-do (KR); Kyoung-soo Kim, Daejeon (KR); Kyu-man Youn, Gyeonggi-do (KR); Hyeon-jin Seo, Gangwon-do (KR); Myung-soo Ko, Seoul (KR); Sang-hoon Lee, Gyeonggi-do (KR); Dong-wan Ryu, Gyeonggi-do (KR); Yeong-eun Kim, Incheon (KR)

Correspondence Address: SUGHRUE MION, PLLC, 2100 PENNSYLVANIA AVENUE, N.W., SUITE 800, WASHINGTON, DC, 20037, US

(73) Assignee: DOOSAN cORPORATION, Seoul (KR)

(21) Appl. No.: 11/817,797

(22) PCT Filed: Nov. 18, 2005
(86) PCT No.: PCT/KR05/03922

§ 371 Date: Sep. 5, 2007

(30) Foreign Application Priority Data
Mar. 5, 2005 (KR) 10-2005-0018445

(51) Int. Cl. C07F 9/02

(52) U.S. Cl. 556/13

(57) ABSTRACT

Disclosed are a deuterated novel iridium complex phosphorescent material used as a light-emitting layer material of an organic electroluminescence device, a preparation method thereof and an organic electroluminescence device using the same. Compared with an organic electroluminescence device using the prior art light-emitting layer with no deuterium substitution, the organic electroluminescence device using the deuterated material of the present invention has improved luminescence efficiency, luminance, power efficiency, thermal stability and the like.

### TECHNICAL FIELD

The present invention relates to a deuterated novel iridium complex phosphorescence material to be used as a luminescent material of an organic electroluminescence device, a preparation method thereof, and an organic electroluminescence device using the same

### BACKGROUND ART

In general, materials for a light-emitting layer are divided into a fluorescent material and a phosphorescent material depending on their light-emitting mechanism. A phosphorescent material normally contains several ligands coordinated to a heavy central metal atom, and it has been known to exhibit higher luminescence efficiency compared with a fluorescent material having 25% of triplet exiton forming probability, its electron transition from triplet state, which is supposed not to occur according to selection rules, is allowed, so that triplet exitons having 75% of triplet exiton forming probability can be used.

As known iridium complex luminescent materials, there are Ir(ppy)₃ (Universal Display Corporation) and Ir(ppy)₂(acac) (WO 2004/043974 A1).

U.S. Pat. No. 6,699,599 discloses a luminescent material obtained by substituting deuterium for some or all of hydrogen atoms of Ir(ppy)₃. In general, when the substitution with deuterium occurs, exitons are easily formed, which improves the luminescence efficiency. It is because in case that hydrogen is substituted with deuterium, the bond strength between carbon and deuterium is greater than that between carbon and hydrogen, and thus, the bond length between carbon and deuterium becomes small, which makes van der Waals' force small. Accordingly, the higher fluorescent efficiency is obtained.

However, U.S. Pat. No. 6,699,599 does not specifically describe the extent to which the efficiency is improved by substituting hydrogen of Ir(ppy)₃ with deuterium as numerical values, as compared to the case where the substitution does not occur. It can only be presumed from FIGS. 8 and 9 that the efficiency is slightly improved.

### DISCLOSURE OF INVENTION

### Technical Solution

Therefore, an object of the present invention is to provide a deuterated novel iridium complex phosphorescence material having improved luminescence efficiency, current efficiency, power efficiency, thermal stability and the like, preparation method thereof and an organic electroluminescence device using the same.

The foregoing and other objects, features, aspects and advantages of the present invention will become more apparent from the following detailed description of the present invention when taken in conjunction with the accompanying drawings.

### BRIEF DESCRIPTION OF THE DRAWINGS

The accompanying drawings, which are included to provide a further understanding of the invention and are incorporated in and constitute a part of this specification, illustrate examples of the invention and together with the description serve to explain the principles of the invention.

In the drawings:

FIG. 1 is a ¹H-NMR spectrum of iridium dimmer Ir(ppy)₂Cl₂-d16 prepared in Example 1 of the present invention;

FIG. 2 is a ¹H-NMR spectrum of iridium complex Ir(ppy)₂(acac)-d8 prepared in Example 1 of the present invention;

FIG. 3 is a mass spectrum of iridium complex Ir(piq)₂(acac)-d8 prepared in Example 4 of the present invention;

FIG. 4 is a UV spectrum of iridium complex Ir(ppy)₂(acac)-d8 prepared in Example 1 of the present invention;

FIG. 5 is a PL spectrum of iridium complex Ir(ppy)₂(acac)-d8 prepared in Example 1 of the present invention;

FIG. 6 is a graphical plot of current-voltage characteristics of an organic electroluminescence device comprising a light-emitting layer doped with the prior art iridium complex Ir(ppy)₂(acac) in an amount of 10%;

FIG. 7 is an electroluminescence spectrum of an organic electroluminescence device comprising a light-emitting layer doped with prior art iridium complex Ir(ppy)₂ (acac) in an amount of 10%;

FIG. 8 is a graphical plot of current-voltage characteristics of an organic electroluminescence device comprising a light-emitting layer doped with iridium complex Ir(ppy)₂(acac)-d8 prepared in Example 1 of the present invention in an amount of 10%;

FIG. 9 is an electroluminescence spectrum of an organic electroluminescence device comprising a light-emitting layer doped with iridium complex Ir(ppy)₂(acac)-d8 prepared in Example 1 of the present invention in an amount of 10%;

FIG. 10 is a graphical plot showing current efficiencies of the organic electroluminescence devices comprising light-emitting layers doped respectively with the prior art iridium complex Ir(ppy)₂(acac) and iridium complex Ir(ppy)₂(acac)-d8 prepared in Example 1 of the present invention in an amount of 10%; and

FIG. 11 is a graphical plot showing power efficiencies of the organic electroluminescence devices comprising light-emitting layers doped respectively with the prior art iridium complex Ir(ppy)₂(acac) and iridium complex Ir(ppy)₂(acac)-d8 prepared in Example 1 of the present invention in an amount of 10%.

### MODE FOR THE INVENTION

Even though hydrogen atoms present in ligands coordinated to metal are substituted with deuterium, most of the chemical properties of an organic phosphorescent material are barely changed. However, because the atomic mass of deuterium is twice as great as that of hydrogen, important physical properties can be changed if hydrogen atoms of a complex are substituted with deuterium atoms. Namely, a heavy atom has a lower zero point energy due to its lower potential energy level and has a lower vibration energy level due to its smaller vibration mode. Accordingly, if hydrogen atoms are substituted with deuterium atoms existing in a compound, van der Waals' force decreases, and proton efficiency decrease due to intermolecular collision by vibration can be prevented.

Based on the aforementioned facts, in the present invention, deuteriums are substituted for some or all of hydrogen atoms present in ligands of an iridium complex, so as to provide a deuterated novel iridium complex phosphorescent material having improved luminescence efficiency, luminance, current efficiency, power efficiency, thermal stability and the like, and an organic electroluminescence device using the same.

A deuterated novel iridium complex in accordance with the present invention has a structure represented by the following Formula 1:

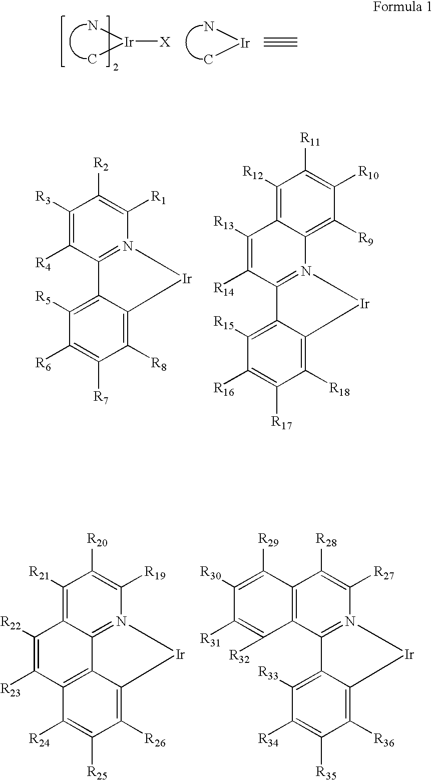

wherein at least one of R₁ to R₃₆ are independently deuterium atoms, and R₁ to R₃₆ which are not deuterium atoms are independently hydrogen, substituted or unsubstituted C₁-C₃₀ alkyl, substituted or unsubstituted C₁-C₃₀ alkenyl, substituted or unsubstituted C₁-C₃₀ condensation ring, substituted or unsubstituted C₁-C₃₀ aryl, substituted or unsubstituted C₁-C₃₀ arylalkyl, substituted or unsubstituted C₁-C₃₀ aryloxy, substituted or unsubstituted C₁-C₃₀ heteroaryl, substituted or unsubstituted C₁-C₃₀ cycloalkyl, substituted or unsubstituted C₁-C₃₀ hetero cycloalkyl, or a halogen atom;

X is a bidentate ligand having a structure represented by the following Formula 2a or 2b:

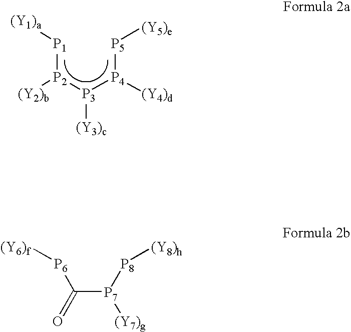

wherein Y₁ to Y₈ are independently selected from the group consisting of hydrogen, deuterium, substituted or unsubstituted C₁-C₃₀ alkyl, substituted or unsubstituted C₁-C₂₀ alkenyl, substituted or unsubstituted C₆-C₃₀ aryl, substituted or unsubstituted C₆-C₃₀ aryloxy, substituted or unsubstituted C₂-C₃₀ heteroaryl, substituted or unsubstituted C₂-C₃₀ heteroarylalkyl, substituted or unsubstituted C₂-C₃₀ heteroaryloxy, substituted or unsubstituted C₅-C₂₀ cycloakyl or substituted or unsubstituted C₂-C₂₀ heterocycloakyl;

P₁ to P₈ are independently a carbon, an oxygen, a nitrogen or a sulfur atom; and

a to h are respectively 0, 1 or 2.

Specific examples of X may includes acetyl acetonate (acac), hexafluoroacetyl acetonate (hfacac), salicylidene (sal), picolinate (pic), 8-hydroxyquinolinate, L-proline (L-pro), debenzoyl methane, tetramethylheptandion (tmd), 1-(2-hydroxypenyl)pyrazolate (oppz) or the like, having any one of structures shown in Formula 3 below.

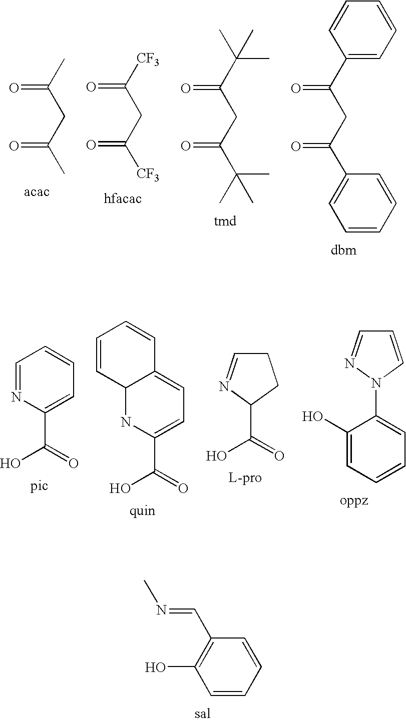

A preparation method of a novel iridium complex represented by Formula 1 in accordance with the present invention will now be described.

A compound of Formula 1 in accordance with the present invention can be obtained from the reaction of the compound of Formula 2a or 2b as defined above with an iridium dimer represented by the following Formula 4:

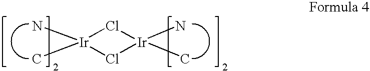

In this reaction, preferably, one mole of the compound of Formula 4 is reacted with two or more moles of the compound of Formula 2a or 2b. As a reaction solvent, 2-ethoxyethanole, ethanol or glycerol may be preferably used, but limited thereto, and a reaction temperature may be preferably in the range of from 70° C. to 200° C. As a base, K₂CO₃, Na₂CO₃, Cs₂CO₃ or the like may be preferably used.

The compound of Formula 4 is obtained by the reaction of Iridium trichloride (IrCl₃.3H₂O) with any one of the compounds represented by the following Formula 5.

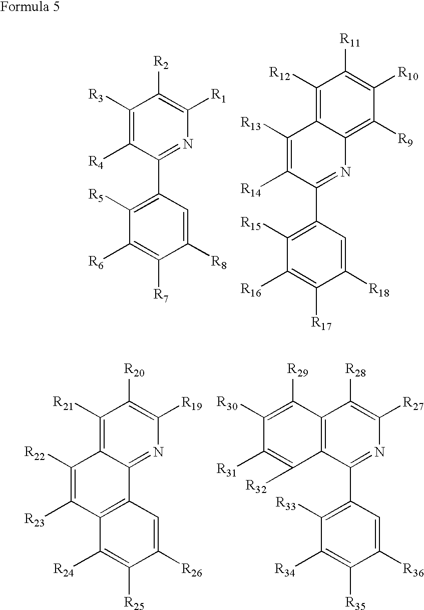

wherein R₁ to R₃₆ are the same as those defined in Formula 1 above. Preferably, in preparing the compound of Formula 4, one mole of Iridium trichloride (IrCl₃.3H₂O) is preferably reacted with two or more moles of the compound of Formula 5. As a reaction solvent, 2-ethoxyethanol, water or glycerol may be preferably used, and a reaction temperature is preferably in the range of from 70° C. to 200° C.

### EXAMPLES

The present invention will now be described through examples in more detail. However, examples are to illustrate the present invention, and not to limit the scope of the present invention thereto.

In the present invention, the structures of the compounds synthesized by the method described above were determined by ¹H-NMR spectroscopy, elementary analysis, mass spectroscopy and the like. UV and PL spectra were observed by dissolving the compound in dichloromethane. Electroluminescence devices were manufactured using the compounds prepared in examples and their luminescence characteristics were evaluated.

### Example 1

### Preparation of Ir(ppy)₂(acac)-d8

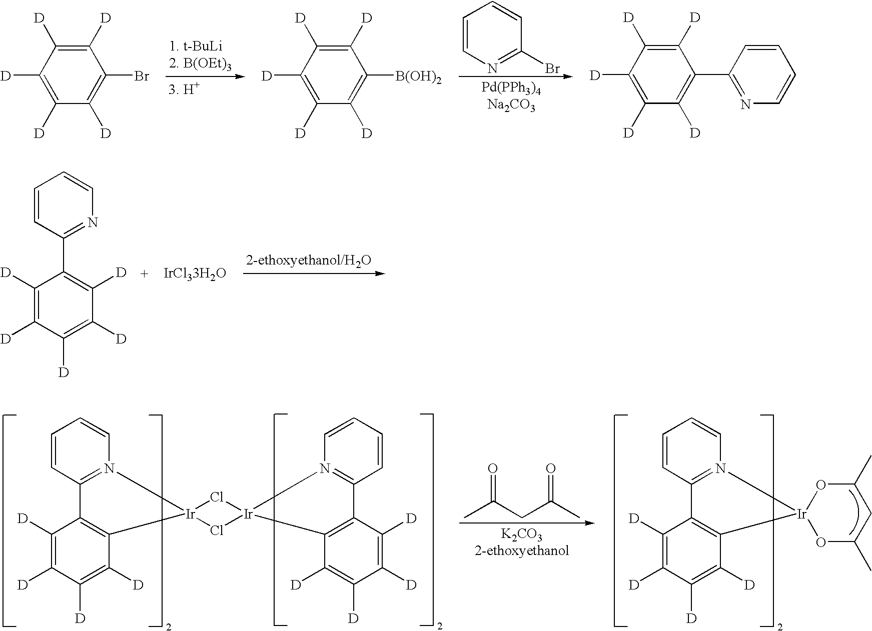

After 2.0 g (12.3 mmol) of bromobenzene-d5 was dissolved in 60 ml of tetrahydrofuran (THF), t-BuLi (25.8 mmol) was slowly added thereto at −78° C. The reaction solution was then stirred at the same temperature for 30 minutes, and then 4.2 ml (24.6 mmol) of B(OEt)₃ was slowly added thereto. The temperature of the reaction solution was slowly raised to room temperature, and the reaction solution was stirred at room temperature for 12 hours. 1N aqueous HCl solution was added to the reaction solution, which was then stirred for another 1 hour, and ethyl acetate was added thereto, thereby extracting the reaction solution. Organic layers were sufficiently washed with water and dried with MgSO₄, and solvent was evaporated under a reduced pressure. A column chromatography was performed with 10% methanol in dichloromethane to give 1.10 g (69%) of phenylboronic acid-d5.

0.36 g (2.87 mmol) of phenylboronic acid and 0.45 g (2.87 mmol) of 2-bromopyridine were put into a mixture of 3 ml of toluene and 1.5 ml of ethanol, and the resultant solution was stirred. Then, 0.1 g (0.089 mmol) of Pd(PPh₃)₄ and 3 ml of 2M aqueous Na₂CO₃ solution were added to the above solution. The reaction mixture was reacted by refluxing while being stirred under a nitrogen atmosphere for five hours, and was cooled down to room temperature. The reaction solution was poured into water and extracted with ethyl acetate. Organic layers were dried with MgSO₄ and evaporated under a reduced pressure. The residue was then purified by column chromatography (eluent: 10% ethyl acetate/n-hexane), to obtain 0.296 g (64%) of 2-phenylpyridine-d5 as a pure product.

0.296 g (1.847 mmol) of 2-phenylpyridine-d5 and 0.184 g (0.616 mmol) of IrCl₃.3H₂O were dissolved in 15 ml of 2-ethoxyethanol and 4.5 ml of water, and the resulting mixture was then reacted at 140° C. for 24 hours. The temperature of the reaction solution was cooled down to room temperature, and a yellow solid obtained by filtration of the reaction solution was washed with 95% ethanol, acetone and n-hexane in order, to obtain 0.228 g (34%) of iridium dimmer as a yellow solid.

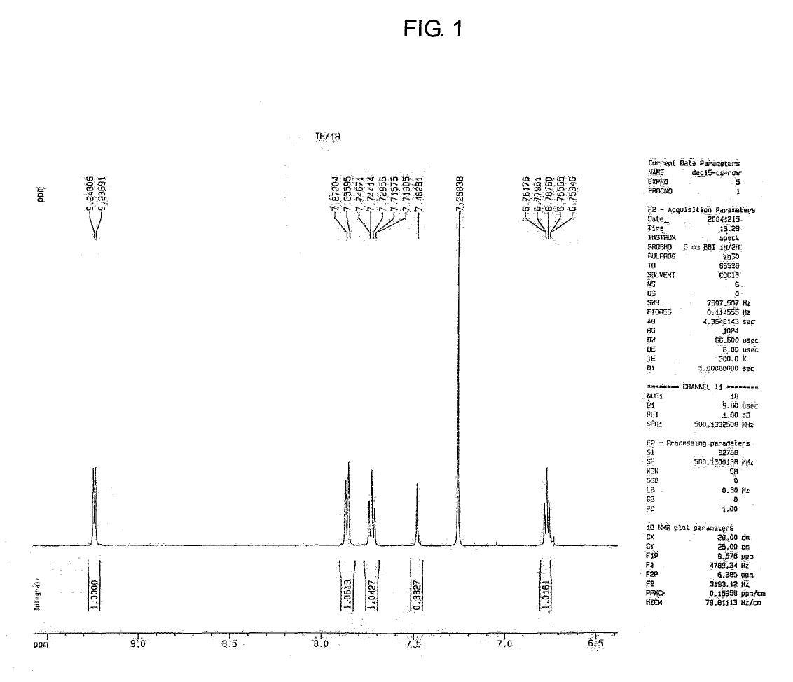

¹H-NMR (CDCl₃, 500 MHz) δ(ppm) 9.24 (d, 1H), 7.86 (d, 1H), 7.74 (t, 1H), 6.77 (t, 1H) (See FIG. 1)

228 mg (0.210 mmol) of iridium dimmer obtained above, 53 mg (0.53 mmol) of acetyl acetonate and 223 mg (2.10 mmol) of Na₂CO₃ were put into 10 ml of 2-ethoxyethanol, and the resulting mixture was reacted at 140° C. for 15 hours. The temperature of the reaction solution was lowered to room temperature, and water was added thereto, thereby inducing crystallization. Then, a solid was filtered, and then washed with ether and n-hexane. The obtained solid was dissolved in dichloromethane, and then purified by a column chromatography to give 240 mg (80%) of pure desired compound.

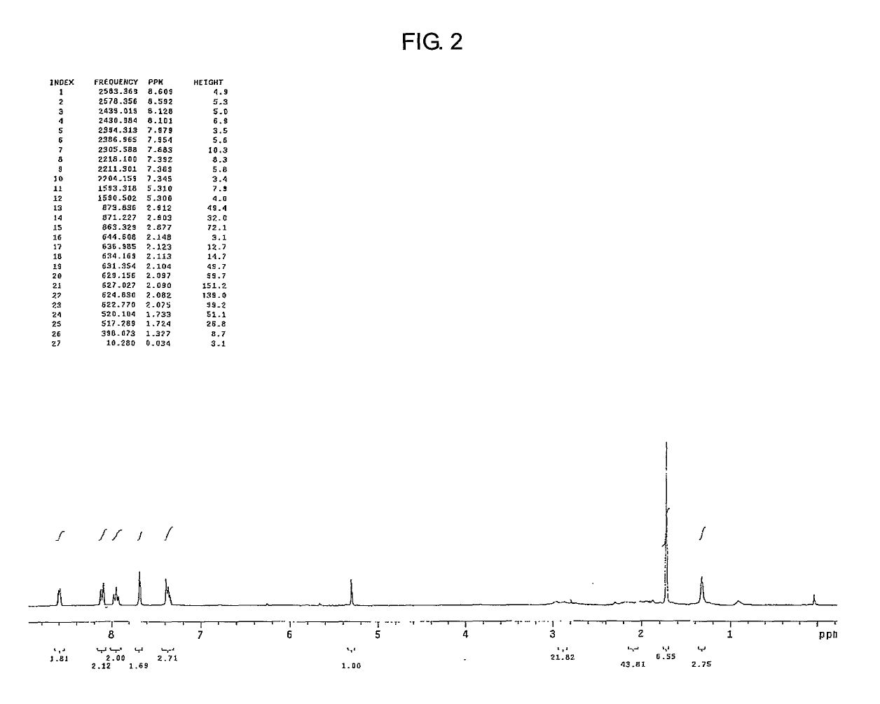

¹H-NMR (CDCl₃, 300 MHz) δ(ppm) 8.60 (d, 2H), 8.11 (d, 2H), 7.95(t, 2H), 7.36(t, 2H), 5.30(s, 1H), 1.72(s, 6H) (See FIG. 2)

Elemental analysis: Found: C 53.54, H 5.01, N 4.60; Calculated: C 53.36, H 5.14, N 4.61

### Example 2

### Preparation of Ir(ppy)₂(acac)-d16

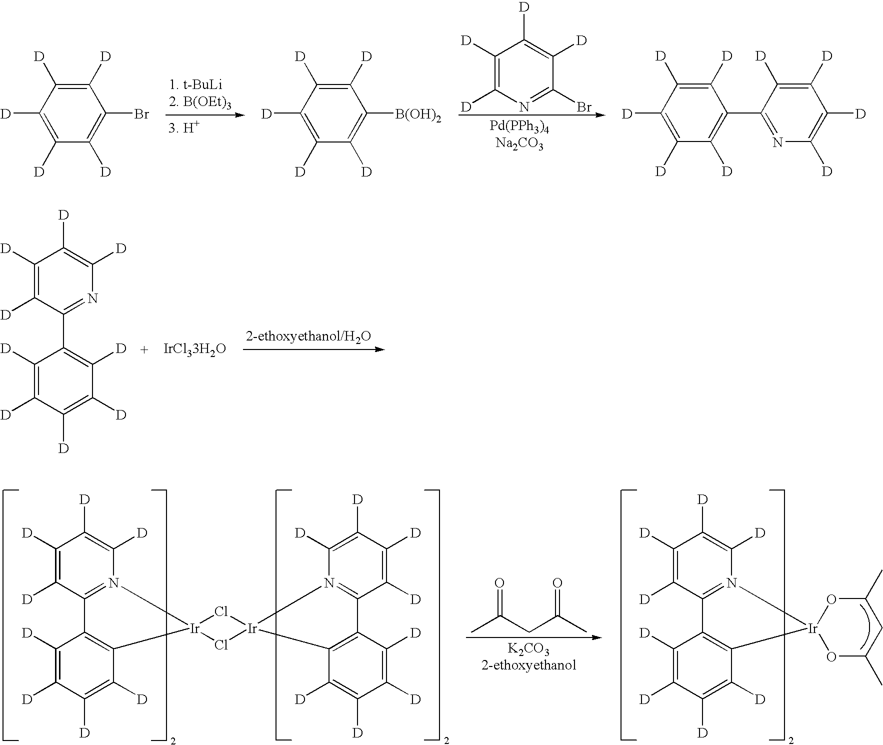

Using the same procedure as described in Example 1, except for using 2-bromopyridine-d4 instead of 2-bromopyridine, 2-phenylpyridine-d9 was obtained.

1.0 g (3.35 mmol) of Iridium trichloride (IrCl₃.3H₂O) and 1.4 ml (10.0 mmol) of 2-phenylpyridine-d9 were added to a solution obtained by mixing 80 ml of 2-ethoxyethanol and 25 ml of water, and the resulting mixture was then reacted at 140° C. for 24 hours. After the temperature of the reaction solution was lowered to room temperature, and the precipitate generated was filtered, and then washed with ethanol and acetone. The filtered solid was dried in vacuo, to obtain 1.2 g (33% yield) of iridium dimer as a yellow solid.

1.1 g (1 mmol) of the obtained iridium dimer, 0.25 g (2.5 mmol) of acetyl acetonate and 10 ml of 2N aqueous K₂CO₃ solution were added into 20 ml of ethanol, and the resulting mixture was then reacted by refluxing for 24 hours. A generated solid was filtered and then washed with ethanol and acetone, to obtain the desired compound with an yield of 80%.

¹H-NMR (CDCl₃, 300 MHz) δ (ppm) 5.25 (s, 1H), 1.69 (s, 6H)

Elemental analysis: Found: C 52.50, H 6.31, N 4.47; Calculated: C 52.66, H 6.38, N 4.55

### Example 3

### Preparation of Ir(ppy)₂(L-pro)-d16

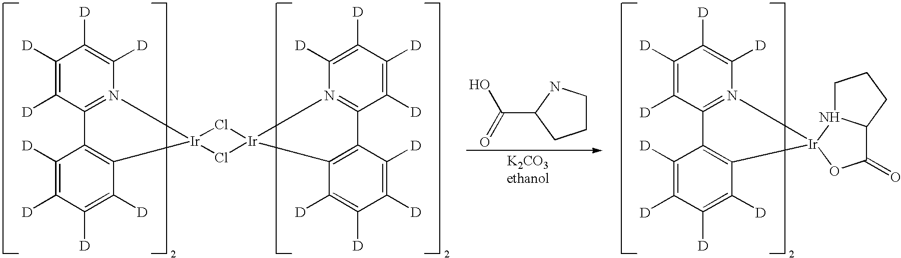

1.1 g (1 mmol) of iridium dimer prepared as described in Example 2, 0.29 g (2.5 mmol) of L-proline, and 10 ml of 2N aqueous K₂CO₃ solution were added into 20 ml of ethanol, and the resulting mixture was then reacted by refluxing for 24 hours. A generated solid was filtered, and then washed with ethanol and acetone, to obtain the desired compound an yield of 85%.

¹H-NMR (CDCl₃, 300 MHz) δ (ppm) 5.45 (s, 1H), 2.90 (m, 1H), 1.95 (m, 1H), 1.21 (m, 5H) Elemental analysis: Found: C 50.89, H 6.34, N 6.45. Calculated: C 51.41, H 6.39, N 6.66

### Example 4

### Preparation of Ir(piq)₂(acac)-d8

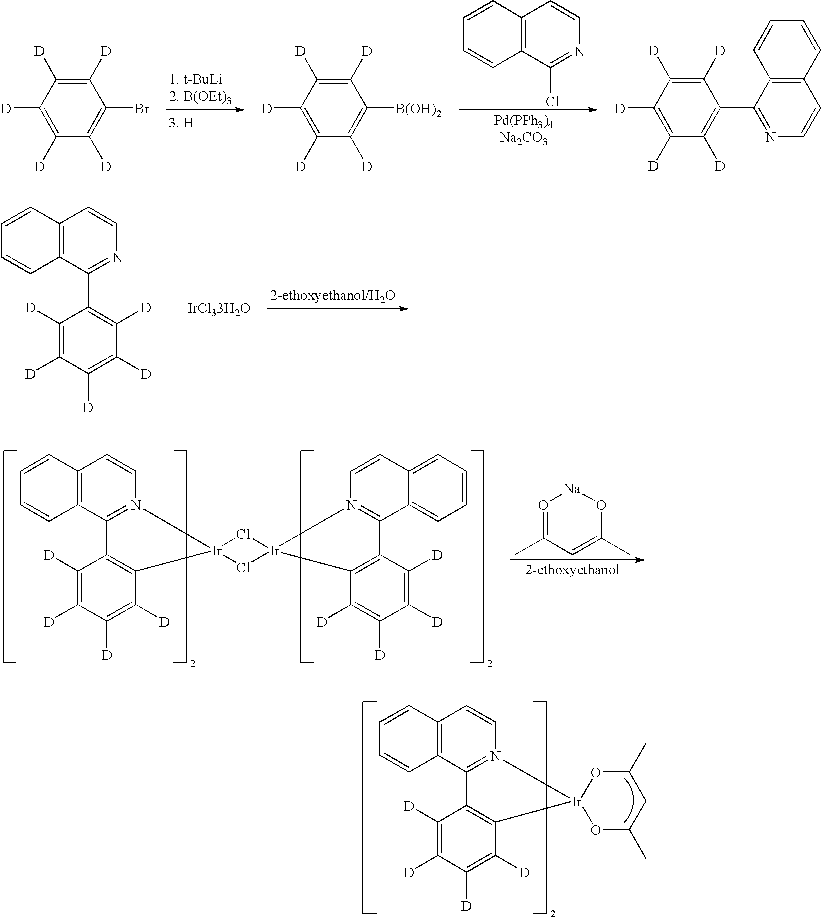

2.0 g (12.3 mmol) of bromobenzene-d5 was dissolved in 60 ml of tetrahydrofuran (THF), and then, t-BuLi (25.8 mmol) was slowly added thereto at −78° C. Then, the reaction solution was stirred at the same temperature for 30 minutes, and 4.2 ml (24.6 mmol) of B(OEt)₃ was slowly added thereto. The temperature of the reaction solution was slowly raised to room temperature and the reaction solution was then stirred at room temperature for 12 hours. 1N aqueous HCl solution was added to the reaction solution, which was stirred at room temperature for additional 1 hour, and then extracted with ethyl acetate. Organic layers were sufficiently washed with water, dried with MgSO₄, and evaporated under a reduced pressure. The residue was purified by a column chromatography with 10% methanol/dichloromethane, to obtain 1.10 g (69%) of phenylboronic acid-d5.

1.49 g (12.2 mmol) of phenylboronic acid-d5 and 2.0 g (12.2 mmol) of 2-chloroisoquinoline were added into 13 ml of toluene and 6.5 ml of ethanol, the resulting mixture was then stirred. Then, 0.44 g (0.38 mmol) of Pd(PPh₃)₄ and 13 ml of 2M aqueous Na₂CO₃ solution were added to the reaction solution. The reaction solution was reacted by refluxing while being stirred under a nitrogen atmosphere for 5 hours, and then cooled down to room temperature. The reaction solution was poured into water and then extracted with ethyl acetate. Organic layers were dried with MgSO₄ and evaporated under a reduced pressure. And then the obtained compound was purified by a column chromatography (eluent: toluene/n-hexane=2/1), to obtain 2.279 g (91%) of 2-phenylisoquinoline-d5 as a pure product.

2.0 g (9.51 mmol) of 2-phenylisoquinoline-d5 and 0.947 g (3.17 mmol) of IrCl₃.3H₂ O were dissolved in 80 ml of 2-ethoxyethanol and 25 ml of water, and the resulting mixture was then reacted at 140° C. for 24 hours. The temperature of the reaction solution was lowered to room temperature, and the reaction solution was filtered to obtain a red solid, which was then washed with 95% ethanol, acetone and n-hexane in order, to obtain 1.54 g (76%) of iridium dimer as a red solid.

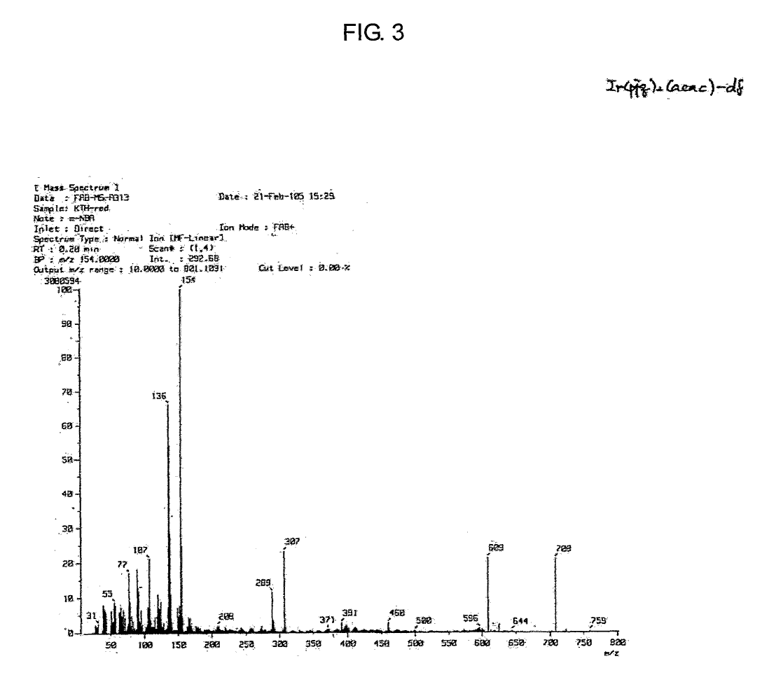

1.54 g (1.20 mmol) of the above obtained iridium dimer and 0.36 g (2.99 mmol) of acetyl acetonate sodium salt were added into 50 ml of 2-ethoxyethanol and the resulting mixture was reacted at 140° C. for 15 hours. The temperature of the reaction solution was lowered to room temperature, and a solid was filtered and then was washed with ether and n-hexane. The obtained solid was dissolved in dichloromethane, and then purified by a column chromatography, to obtain 1.45 g (85%) of pure desired compound. The structure of the final product was identified with mass spectroscopy, and its mass spectrum is shown in FIG. 3.

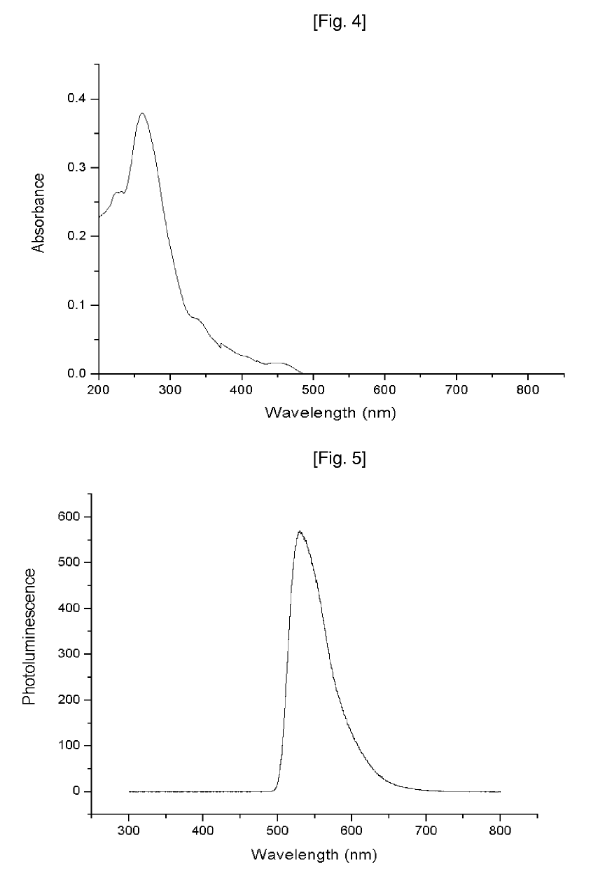

FIGS. 4 and 5 illustrate UV and PL spectra of Ir(ppy)₂(acac)-d8 prepared in Example 1. In order to compare with the luminescence properties of the deuterated iridium complex of the present invention, Ir(ppy)₂(acac), was synthesized according to the known method. Then, two electroluminescence devices having the following structures were constructed by respectively using Ir(ppy)₂(acac) and Ir(ppy)₂(acac)-d8 prepared in the Example 1. Also, their luminescence properties were evaluated.

ITO/NPB (40 nm)/CBP+10% Ir(ppy)₂(acac) (20 nm)/BCP (10 nm)/Alq₃ (40 nm)/LiF (1 nm)/Al

ITO/NPB (40 nm)/CBP+10% Ir(ppy)₂(acac)-d8 (20 nm)/BCP (10 nm)/Alq₃ (40 nm)/LiF(1 nm)/Al

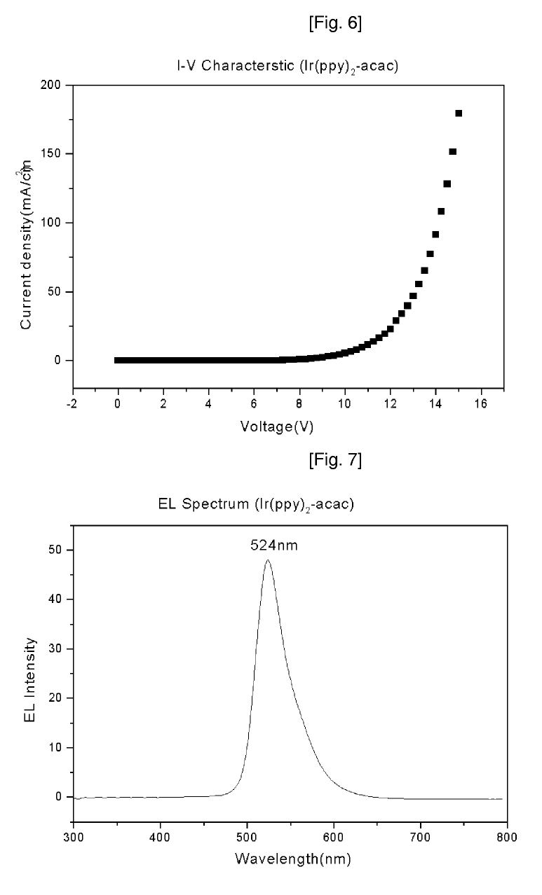

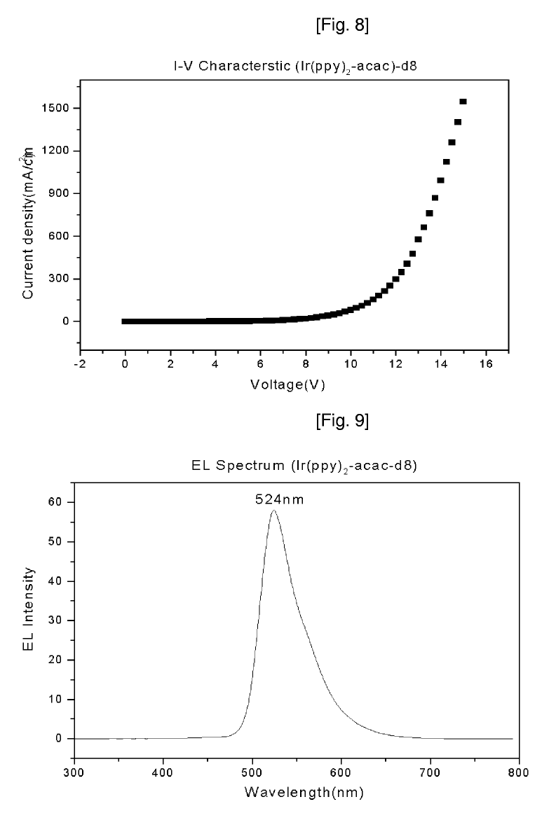

FIGS. 6 and 7 respectively illustrate voltage-current characteristics and an EL spectrum of Ir(ppy)₂(acac), and FIGS. 8 and 9 respectively illustrate voltage-current characteristics and an EL spectrum of Ir(ppy)₂(acac)-d8. From FIG. 9, it can be seen that the novel iridium complex Ir(ppy)₂(acac)-d8 prepared in Example 1 of the present invention and the prior art Ir(ppy)₂(acac) exhibit similar luminescence characteristics.

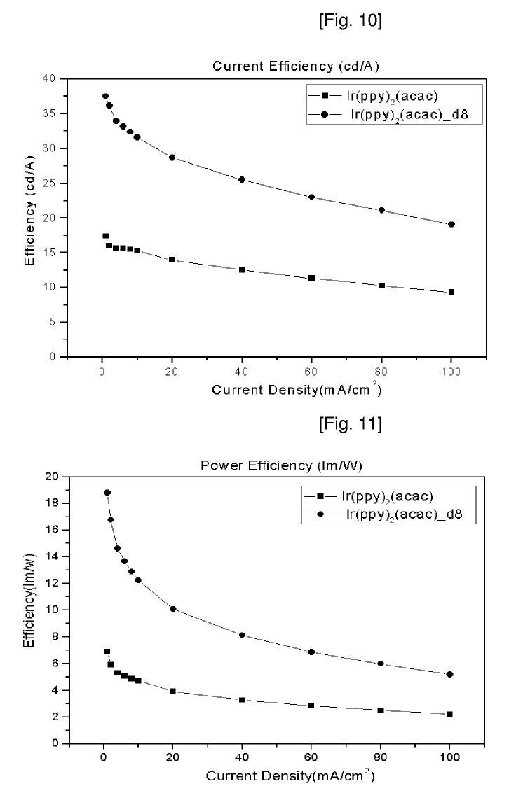

Table 1 below shows luminance, current efficiency and power efficiency of Ir(ppy)₂ (acac). Table 2 shows luminance, current efficiency and power efficiency of Ir(ppy)₂ (acac)-d8. FIGS. 10 and 11 respectively illustrate the luminance and power efficiency of Ir(ppy)₂(acac) and Ir(ppy)₂(acac)-d8.

TABLE 1

| Current | Current | Voltage | Luminance | Color | | |
|---|---|---|---|---|---|---|
| (mA) | Density(mA/cm2) | (V) | (cd/m2) | Coordinate(CIE) | Efficiency(cd/A) | Efficiency(lm/w) |
| 0.04 | 1 | 7.94 | 174 | (0.300, 0.650) | 17.40 | 6.88 |
| 0.08 | 2 | 8.51 | 321 | (0.301, 0.649) | 16.05 | 5.92 |
| 0.16 | 4 | 9.23 | 626 | (0.301, 0.649) | 15.65 | 5.32 |
| 0.24 | 6 | 9.62 | 937 | (0.301, 0.649) | 15.61 | 5.09 |
| 0.32 | 8 | 9.96 | 1240 | (0.301, 0.648) | 15.50 | 4.88 |
| 0.4 | 10 | 10.2 | 1530 | (0.302, 0.648) | 15.30 | 4.71 |
| 0.8 | 20 | 11.12 | 2790 | (0.302, 0.648) | 13.95 | 3.93 |
| 1.6 | 40 | 12.04 | 5020 | (0.302, 0.647) | 12.55 | 3.27 |
| 2.4 | 60 | 12.52 | 6800 | (0.302, 0.656) | 11.33 | 2.84 |
| 3.2 | 80 | 12.87 | 8220 | (0.302, 0.645) | 10.27 | 2.50 |
| 4.0 | 100 | 13.26 | 9370 | (0.301, 0.646) | 9.37 | 2.20 |

TABLE 2

| | Current | | | | | |
|---|---|---|---|---|---|---|
| Current | Density | Voltage | Luminance | Color | | |
| (mA) | (mA/cm2) | (V) | (cd/m2) | Coordinate(CIE) | Efficiency(cd/A) | Efficiency(lm/w) |
| 0.04 | 1 | 6.26 | 375 | (0.307, 0.648) | 37.50 | 18.80 |
| 0.08 | 2 | 6.77 | 723 | (0.308, 0.647) | 36.15 | 16.76 |
| 0.16 | 4 | 7.30 | 1360 | (0.307, 0.646) | 34.00 | 14.62 |
| 0.24 | 6 | 7.62 | 1990 | (0.308, 0.646) | 33.16 | 13.66 |
| 0.32 | 8 | 7.88 | 2590 | (0.307, 0.646) | 32.37 | 12.90 |
| 0.4 | 10 | 8.10 | 3160 | (0.307, 0.645) | 31.60 | 12.24 |
| 0.8 | 20 | 8.94 | 5740 | (0.307, 0.644) | 28.70 | 10.08 |
| 1.6 | 40 | 9.86 | 10200 | (0.307, 0.643) | 25.50 | 8.12 |
| 2.4 | 60 | 10.52 | 13800 | (0.306, 0.652) | 23.00 | 6.86 |
| 3.2 | 80 | 11.07 | 16900 | (0.306, 0.641) | 21.13 | 5.99 |
| 4.0 | 100 | 11.55 | 19100 | (0.306, 0.641) | 19.10 | 5.19 |

From the above result, it can be seen that the novel iridium complex in accordance with the present invention exhibits the luminance and current efficiency improved more than twice as those of the prior art Ir(ppy)₂(acac) (See FIG. 10) and the power efficiency improved two or three two or three times as that of the prior art Ir(ppy)₂ (acac) (See FIG. 12), while exhibiting similar luminescence properties to those of Ir(ppy)₂(acac).

In general, if deuterium is substituted for hydrogen of ligands, quantum and luminescence efficiencies can be slightly improved. For example, Ir(ppy)₃-d24 disclosed in U.S. Pat. No. 6,699,599 has the power efficiency of about 15 lm/W at 6.26V. However, it could not be expected that they would be improved 2 to 3 times as shown in the present invention. That is, as can be seen from FIG. 11, Ir(ppy)₂(acac)-d8 according to the present invention has remarkably improved power efficiency of about 19 lm/W at 6.26V. Accordingly, when the deuterated novel iridium complex phosphorescent material in accordance with the present invention is used as a light-emitting layer of an organic electroluminescence device, the luminescence efficiency, the luminance characteristics and the power efficiency are improved as compared to a commonly-used luminescent material with no deuterium substitution.

In accordance with the present invention, a deuterated novel iridium complex phosphorescent material having improved luminescence efficiency, luminance, current efficiency, power efficiency, thermal stability and the like, a preparation method thereof and an organic electroluminescence device using the same are provided. The iridium complex in accordance with the present invention exhibits the luminance and current efficiency improvement twice and the power efficiency improvement two or three times, compared with those of the prior iridium complex, with no change in other light-emitting properties, and thus, it is expected to be used as a material of a light-emitting layer of an organic electroluminescence device.

As the present invention may be embodied in several forms without departing from the spirit or essential characteristics thereof, it should also be understood that the above-described examples are not limited by any of the details of the foregoing description, unless otherwise specified, but rather should be construed broadly within its spirit and scope as defined in the appended claims, and therefore all changes and modifications that fall within the metes and bounds of the claims, or equivalence of such metes and bounds are therefore intended to be embraced by the appended claims.

1. A deuterated Iridium complex represented by the following Formula 1: 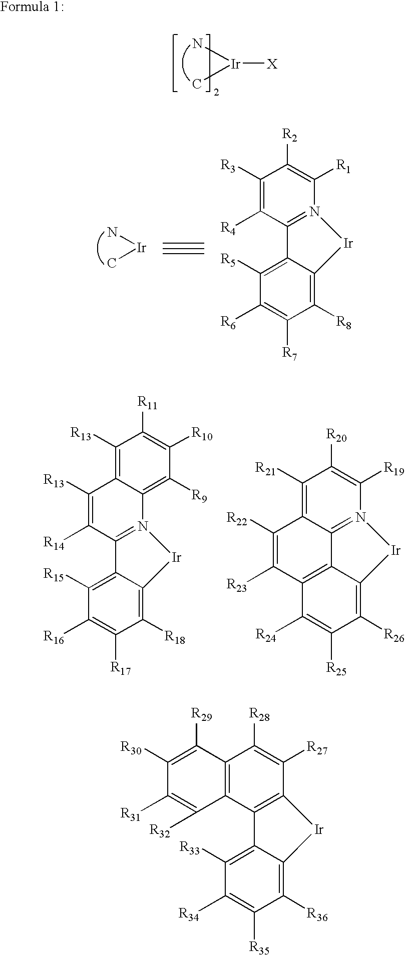
wherein at least one of R₁ to R₃₆ are independently deuterium atoms, and R₁ to R₃₆ which are not deuterium atoms are independently hydrogen, substituted or unsubstituted C₁-C₃₀ alkyl, substituted or unsubstituted C₁-C₃₀ alkenyl, substituted or unsubstituted C₁-C₃₀ condensation ring, substituted or unsubstituted C₁-C₃₀ aryl, substituted or unsubstituted C₁-C₃₀ arylalkyl, substituted or unsubstituted C₁-C₃₀ aryloxy, substituted or unsubstituted C₁-C₃₀ heteroaryl, substituted or unsubstituted C₁-C₃₀ cycloalkyl, substituted or unsubstituted C₁-C₃₀ hetero cycloalkyl, or a halogen atom;
X is a bidentate ligand having a structure represented by the following Formula 2a or 2b: 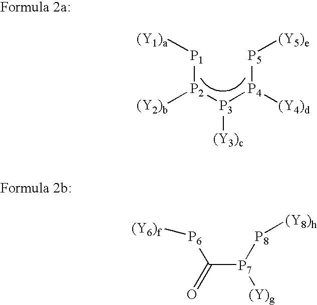
wherein Y₁ to Y₈ are independently selected from the group consisting of hydrogen, deuterium, substituted or unsubstituted C₁-C₃₀ alkyl, substituted or unsubstituted C₁-C₂₀ alkenyl, substituted or unsubstituted C₆-C₃₀ aryl, substituted or unsubstituted C₆-C₃₀ aryloxy, substituted or unsubstituted C₂-C₃₀ heteroaryl, substituted or unsubstituted C₂-C₃₀ heteroarylalkyl, substituted or unsubstituted C₂-C₃₀ heteroaryloxy, substituted or unsubstituted C₅-C₂₀ cycloakyl, or substituted or unsubstituted C₂-C₂₀ heterocycloakyl;
P₁ to P₈ are independently carbon, oxygen, nitrogen or sulfur atom; and
a to h are respectively 0, 1 or 2.

2. The deuterated iridium complex according to claim 1, wherein X is a bidentate ligand selected from the compounds shown in Formula 3:

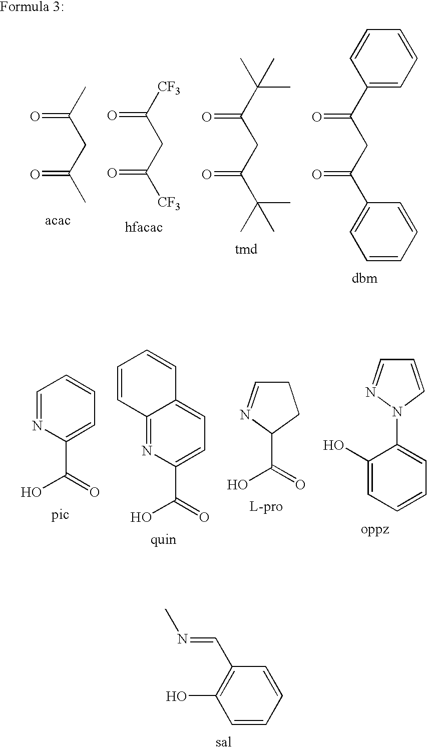

3. The deuterated iridium complex according to claim 1, wherein R₁ to R₃₆ are independently hydrogen or deuterium atom, provided that the iridium complex has at least one deuterium atom.

4. A preparation method of a deuterated iridium complex, comprising:
(1) obtaining a compound represented by Formula 4 by reacting Iridium trichloride with any one compound represented by Formula 5; and
(2) obtaining a compound of Formula 1 by reacting the compound represented by Formula 4 with a compound represented by Formula 2a or 2b: 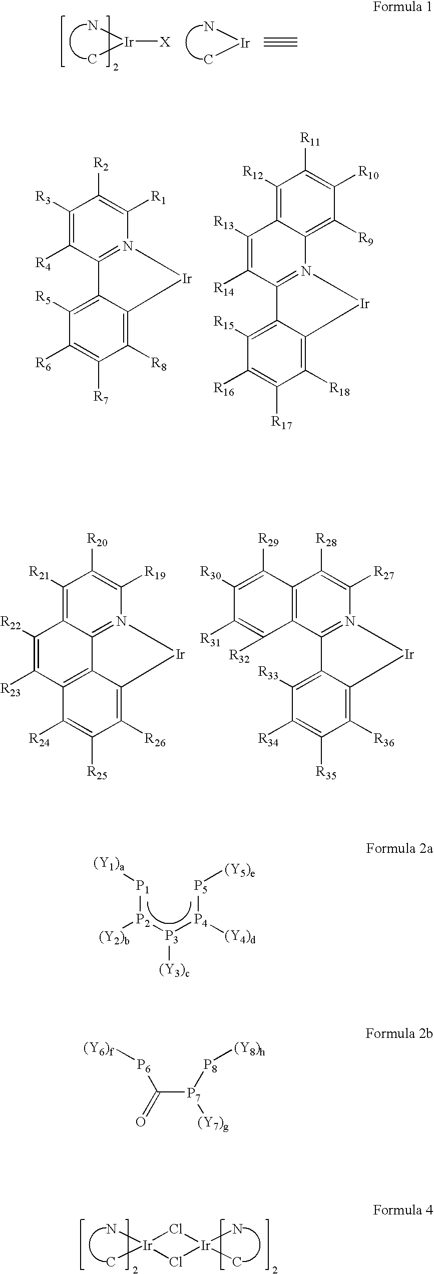 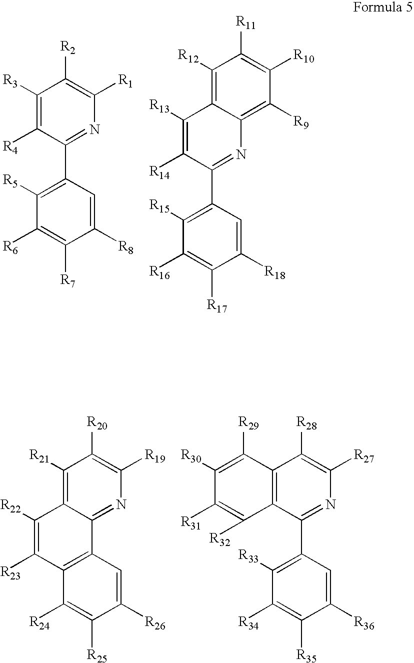
wherein at least one of R₁ to R₃₆ are independently deuterium atoms, and R₁ to R₃₆ which are not deuterium atoms are independently hydrogen, substituted or unsubstituted C₁-C₃₀ alkyl, substituted or unsubstituted C₁-C₃₀ alkenyl, substituted or unsubstituted C₁-C₃₀ condensation ring, substituted or unsubstituted C₁-C₃₀ aryl, substituted or unsubstituted C₁-C₃₀ arylalkyl, substituted or unsubstituted C₁-C₃₀ aryloxy, substituted or unsubstituted C₁-C₃₀ heteroaryl, substituted or unsubstituted C₁-C₃₀ cycloalkyl, substituted or unsubstituted C₁-C₃₀ hetero cycloalkyl, or a halogen atom;
X is a bidentate ligand having a structure represented by Formula 2a or 2b;
Y₁ to Y₈ are independently selected from the group consisting of hydrogen, deuterium, substituted or unsubstituted C₁-C₃₀ alkyl, substituted or unsubstituted C₁-C₂₀ alkenyl, substituted or unsubstituted C₆-C₃₀ aryl, substituted or unsubstituted C₆-C₃₀ aryloxy, substituted or unsubstituted C₂-C₃₀ heteroaryl, substituted or unsubstituted C₂-C₃₀ heteroarylalkyl, substituted or unsubstituted C₂-C₃₀ heteroaryloxy, substituted or unsubstituted C₅-C₂₀ cycloakyl, or substituted or unsubstituted C₂-C₂₀ heterocycloakyl;
P₁ to P₈ are independently carbon, oxygen, nitrogen or sulfur atom; and
a to h are respectively 0, 1 or 2.

5. The method according to claim 4, wherein X is a bidentate ligand selected from the compounds shown in Formula 3:

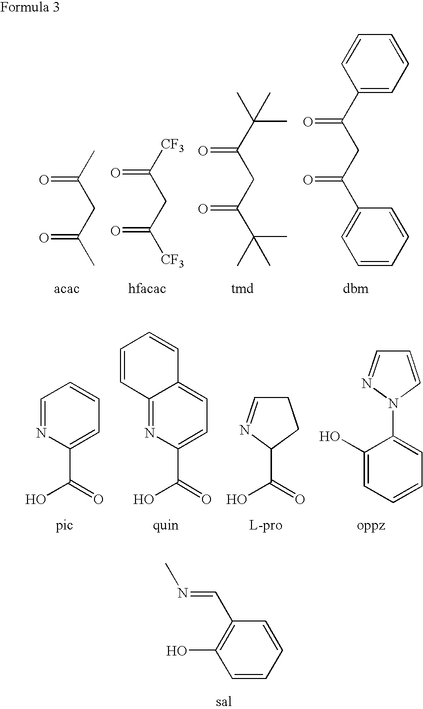

6. The method according to claim 4, wherein in step (1), two or more moles of the compound of Formula 5 is used with respect to one mole of Iridium trichloride, and 2-ethoxyethanol, ethanol or glycerol is used as a reaction solvent.

7. The method according to claim 4, wherein in step (2), two or more moles of the compound of Formula 2a or 2b is used with respect to one mole of the compound of Formula 4, and Iridium trichloride, and 2-ethoxyethanol, ethanol or glycerol is used as a reaction solvent.

8. The method according to claim 4, wherein the reactions in steps (1) and (2) are respectively carried out at 70-200° C.

9. An organic electroluminescence device, comprising an iridium complex according to claim 1 as a material of a light-emitting layer.

10. The deuterated iridium complex according to claim 2, wherein R₁ to R₃₆ are independently hydrogen or deuterium atom, provided that the iridium complex has at least one deuterium atom.

11. The organic electroluminescence device according to claim 9, wherein X is a bidentate ligand selected from the compounds shown in Formula 3:

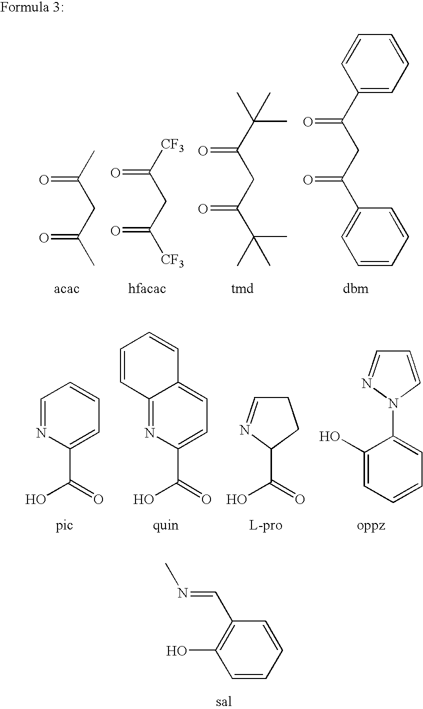

12. The organic electroluminescence device according to claim 9, wherein R₁ to R₃₆ are independently hydrogen or deuterium atom, provided that the iridium complex has at least one deuterium atom.

13. The organic electroluminescence device according to claim 11, wherein R₁ to R₃₆ are independently hydrogen or deuterium atom, provided that the iridium complex has at least one deuterium atom.
